(19) United States
(12) Patent Application Publication
(10) Pub. No.: US 2008/0007993 A1
(43) Pub. Date: Jan. 10, 2008

(54) Semiconductor memory device

(75) Inventors: Masahiro Saitoh, Fukuyama-shi (JP); Shinichi Sato, Fukuyama-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/822,123

(22) Filed: Jul. 2, 2007

(30) Foreign Application Priority Data
Jul. 4, 2006 (JP) 2006-184654

(51) Int. Cl. G11C 11/00

(52) U.S. Cl. 365/158

(57) ABSTRACT

A semiconductor memory device comprises writing means for performing a first writing action for shifting an electric resistance of a variable resistance element from a first state to a second state by applying a first voltage between both ends of a memory cell and a gate potential to a gate of a cell access transistor, and a second writing action for shifting the electric resistance from the second state to the first state by applying a second voltage having a polarity opposite to that of the first voltage between both ends of the memory cell and a gate potential to the gate of the cell access transistor, and the polarity and absolute value of the voltage to be applied to both ends of the variable resistance element in the memory cell to be written in the first writing action is different from those in the second writing action.

### CROSS REFERENCE TO RELATED APPLICATION

This Nonprovisional application claims priority under 35 U.S.C. §119(a) on Patent Application No. 2006-184654 filed in Japan on 4 Jul., 2006 the entire contents of which are hereby incorporated by reference.

### BACKGROUND OF THE INVENTION

1. Field of the Invention

The present invention relates to a semiconductor memory device provided with a memory cell including a variable resistance element having two terminals; that can store information by varying its electric resistance between a first state and a second state when voltages having different polarities are separately applied to both ends thereof, and a cell access transistor whose source or drain is connected to one end of the variable resistance element.

2. Description of the Related Art

There has been proposed a method in which one or more short electric pulses are applied to a thin film or bulk formed of a thin film material having Perovskite structure, especially a CMR (colossal magnetoresistance) material or HTSC (high temperature superconductivity) material to vary its electric characteristics. Since an intensity and current density of an electric field provided by the electric pulse are sufficiently high to vary a physical state of the material, conversely, they are to be sufficiently low so as not to destroy the material itself and this electric pulse may have a polarity either positive or negative. In addition, the material characteristics can be further varied by applying the electric pulse repeatedly several times.

In the above conventional technique, a memory cell array structure using a variable resistance element in which the characteristics to be varied is electric resistance is disclosed in Japanese Unexamined Patent Publication No. 2004-87069 and Japanese Unexamined Patent Publication No. 2004-185755.

FIG. 12 shows one constitution example of the memory cell array incorporating the variable resistance element in the above conventional technique disclosed in the Japanese Unexamined Patent Publication No. 2004-185755. According to the constitution example shown in FIG. 12, one transistor 12 and one variable resistance element 11 are electrically connected to form one memory cell 10. Furthermore, sources of the two memory cells are shared and the sources shared by the memory cells arranged in a row direction are commonly connected to a source line SL1.

FIG. 13 shows a voltage applying condition at the time of programming in the memory cell 10 including one transistor 12 and one variable resistance element 11 in the above conventional technique. In addition, here, the programming is defined as an action to shift a resistance value of the variable resistance element from a low resistance state to a high resistance state, and erasing is defined as an action to shift the resistance value of the variable resistance element from the high resistance state to the low resistance state. Therefore, the programmed state means the high resistance state of the variable resistance element and the erased state means the low resistance state of the variable resistance element. As shown in FIG. 13, +3V, for example is applied to a bit line BL of the cell access transistor 12 and at the same time, the ground potential 0V, for example is applied to a source line SL connected to one end of the variable resistance element 11 to be programmed. In addition, +7V, for example is applied to a word line WL connected to a gate of the cell access transistor 12 connected to the variable resistance element 11 to turn on the cell access transistor 12, so that a current path is formed from a bias voltage of the bit line to the ground potential through the cell access transistor 12 and the variable resistance element 11. Thus, the variable resistance element 11 becomes the high resistance state and the programming is performed in the selected memory cell 10. Meanwhile, as for an unselected memory, the ground potential 0V, for example is applied to an unselected word line, so that the cell access transistor in the unselected memory cell is turned off and a current path from the selected bit line to the ground potential (source line) is not formed, and the programming is not performed in the unselected variable resistance element.

FIG. 14 shows a voltage applying condition at the time of erasing in the memory cell 10 including one transistor 12 and one variable resistance element 11 in the above conventional technique. As shown in FIG. 14, the ground voltage 0V, for example is applied to the bit line BL of the cell access transistor 12 and at the same time, +3V, for example is applied to the source line SL connected to one end of the variable resistance element 11 to be erased. In addition, +7V, for example is applied to the word line WL connected to the gate of the cell access transistor 12 connected to the variable resistance element 11, to turn on the cell access transistor 12, so that a current path is formed from the bias voltage of the source line to the ground potential through the cell access transistor 12 and the variable resistance element 11. Thus, the variable resistance element 11 becomes the low resistance state and the erasing is performed in the selected memory cell 10. Meanwhile, as for an unselected memory cell, when the ground potential 0V, for example is applied to the unselected word line, the cell access transistor in the unselected memory cell is turned off and a current path from the selected source line to the ground potential (bit line) is not formed, so that the erasing is not performed in the unselected variable resistance element.

As described above, the memory cell array can be formed of the memory cell in which one end of the variable resistance element is connected to the source or drain of the cell access transistor. However, according to the conventional technique, the voltage +3V applied to the bit line at the time of the programming cannot be applied to the variable resistance element through the cell access transistor as it is. That is, a voltage dropped by a threshold voltage required to turn the cell access transistor on is applied to the variable resistance element. At this time, as shown in FIGS. 13 and 14, in the case where the voltages applied to the variable resistance element in the programming and erasing actions are in opposite direction, and the voltages required to vary the resistance at the time of the programming and erasing are the same, when a minimum voltage required to be applied to both ends of the variable resistance element at the time of the programming is applied to the bit line, the resistance of the variable resistance element does not vary because the voltage dropped from the minimum voltage by the threshold voltage of the cell access transistor is applied to the variable resistance element. Therefore, the voltage not less than the minimum voltage required to be applied to both ends of the variable resistance element at the time of the programming, +4V, for example has to be applied to the bit line.

Thus, the voltage required for the writing becomes high as a whole in the memory cell, a booster circuit for boosting the bit line voltage is needed, and a chip area is increased. Furthermore, since the voltage to be used becomes high, a power consumption is also increased.

### SUMMARY OF THE INVENTION

The present invention was made in view of the above problems and it is an object of the present invention to provide a semiconductor memory device capable of preventing the chip area and power consumption from being increased by reducing an operation voltage in a writing action for a memory cell comprising a variable resistance element and a cell access transistor.

A semiconductor memory device of the present invention to attain the above object is first characterized by comprising a memory cell having a variable resistance element having two terminals and being capable of storing information in accordance with a shift of an electric resistance between a first state and a second state by applying voltages having different polarities to both ends respectively and a cell access transistor having a source or a drain connected to one end of the variable resistance element, and writing means for performing two writing actions such as a first writing action shifting the electric resistance of the variable resistance element from the first state to the second state by applying a predetermined first voltage between both ends of the memory cell and a predetermined gate potential to a gate of the cell access transistor, and a second writing action shifting the electric resistance of the variable resistance element from the second state to the first state by applying a predetermined second voltage having a polarity opposite to that of the first voltage between both ends of the memory cell and a predetermined gate potential to the gate of the cell access transistor, wherein the polarity and an absolute value of the voltage to be applied to both ends of the variable resistance element in the memory cell to be written in the first writing action are different from those in the second writing action.

According to the semiconductor memory device in the first characteristics, since the memory cell comprises the variable resistance element having a two terminals and being capable of storing information by shifting its electric resistance from the first state to the second state when the first voltage is applied to both ends and shifting its electric resistance from the second state to the first state when the second voltage having the polarity opposite to that of the first voltage is applied to both ends, when the first and second voltages having opposite polarities are applied to both ends of the memory cell to be written respectively, the electric resistance of the variable resistance element can switch between the first state and the second state, whereby the information can be written.

Here, when it is assumed that the cell access transistor is an enhancement-type MOSFET being used in a peripheral circuits of the semiconductor memory device in general, since the first and second voltages applied to both ends of the memory cell have opposite polarities, a voltage dropped by the threshold voltage of the cell access transistor is applied to both ends of the variable resistance element in the first writing action or the second writing action, so that the absolute value of the voltage to be applied to both ends of the variable resistance element in the one writing action can be set so as to be smaller than the absolute value of the voltage to be applied to both ends of the variable resistance element in the other writing action. Thus, since it is not necessary to set the absolute value of one of the first voltage and the second voltage to be applied to both ends of the memory cell at the time of the one writing action to be considerably greater than the other absolute value, the operation voltages in the first and second writing actions can be reduced as a whole. As a result, an unnecessary boosting operation for the operation voltage does not have to be performed and the chip area and the power consumption can be prevented from being increased due to the unnecessary boosting operation.

Furthermore, in addition to the first characteristics, the semiconductor memory device according to the present invention is second characterized in that the polarity and absolute value of a voltage at both ends between the source and drain of the cell access transistor in the memory cell to be written in the first writing action are different from those in the second writing action.

Furthermore, in addition to the second characteristics, the semiconductor memory device according to the present invention is third characterized in that a bias condition of the cell access transistor in each of the first writing action and the second action is set such that the absolute value of the voltage at both ends between the source and the drain of the cell access transistor in the memory cell to be written in either one of the first writing action or the second writing action is smaller than that in the other writing action when the absolute value of the voltage at both ends of the variable resistance element in the memory cell to be written is greater than that in the other writing action.

According to the semiconductor memory device in the second or third characteristics, since the voltage at both ends between the source and the drain of the cell access transistor in the either one writing action of the first writing action or the second writing action can be higher than that in the other writing action, the absolute value of the voltage to be applied to both ends of the variable resistance element in the one writing action can be set so as to be smaller than the absolute value of the voltage to be applied to both ends of the variable resistance element in the other writing action. Thus, the same effect as that of the first characteristic can be provided.

Furthermore, in addition to any one of the above characteristics, the semiconductor memory device according to the present invention is fourth characterized in that the absolute values of the first voltage and the second voltage are the same.

According to the semiconductor memory device in the fourth characteristics, since the absolute values of the first voltage and the second voltage are the same, first voltage used in the first writing action can be used as the second voltage by converting its polarity in the second writing action, for example, so that it is not necessary to generate the first voltage and the second voltage separately and a generation circuit for both first voltage and second voltage can be shared. In addition, since a circuit constitution of the peripheral circuit can be simplified, the chip area can be further reduced.

In addition to any one of the above characteristics, the semiconductor memory device according to the present invention is fifth characterized in that the cell access transistor is an enhancement-type N channel MOSFET.

According to the semiconductor memory device in the fifth characteristics, since an enhancement-type MOSFET that is used in the peripheral circuit of the semiconductor memory device in general can be used as the cell access transistor, it is not necessary to use a special transistor for the memory cell, so that the manufacturing steps of the semiconductor memory device can be simplified and the manufacturing cost can be low.

Furthermore, in addition to the fifth characteristic, the semiconductor memory device according to the present invention is sixth characterized in that the higher one of potentials at both ends of the memory cell to be written is the same level as a gate potential of the cell access transistor in the memory cell to be written in the first writing action.

According to the semiconductor memory device in the sixth characteristics, since the potential level to be applied to one end of the memory cell to be written is the same as the potential level to be applied to the gate of the cell access transistor in the memory cell in the first writing action, both potential level can be shared and the generation circuit for the potential levels can be shared and since the circuit constitution of the peripheral circuit can be simplified, the chip area can be further reduced.

Furthermore, in addition to the fifth or sixth characteristic, the semiconductor memory device according to the present invention is seventh characterized in that the higher one of potentials at both ends of the memory cell to be written is the same level as the gate potential of the cell access transistor in the memory cell to be written in the second writing action.

According to the semiconductor memory device in the seventh characteristic, since the potential level to be applied to one end of the memory cell to be written is the same as the potential level to be applied to the gate of the cell access transistor in the memory cell in the second writing action, both potential level can be shared and the generation circuit for the potential levels can be shared and since the circuit constitution of the peripheral circuit can be simplified, the chip area can be further reduced.

Furthermore, in addition to any one of the fifth to seventh characteristics, the semiconductor memory device according to the present invention is eighth characterized in that the higher one of potentials at both ends of the memory cell to be written in the first writing action is the same level as that of the second writing action.

According to the semiconductor memory device in the eighth characteristics, since the potential level applied to one end of the memory cell to be written in the first writing action is the same as that applied to the other end of the memory cell to be written in the second writing action, both potential level can be shared and the generation circuit for the potential levels can be shared and since the circuit constitution of the peripheral circuit can be simplified, the chip area can be further reduced.

Furthermore, in addition to any one of the fifth to eighth characteristics, the semiconductor memory device according to the present invention is ninth characterized in that the gate potential of the cell access transistor in the memory cell to be written in the first writing action is the same level as that in the second writing action.

According to the semiconductor memory device in the ninth characteristics, since the gate potential of the cell access transistor in the memory cell to be written in the first writing action is the same as that in the second writing action, both potential level can be shared and the generation circuit for the potential levels can be shared and since the circuit constitution of the peripheral circuit can be simplified, the chip area can be further reduced.

Furthermore, in addition to the any one of the above characteristics, the semiconductor memory device according to the present invention is tenth characterized by comprising a memory cell array including the memory cells arranged in a row and column direction, wherein the gates of the cell access transistors in the memory cells arranged in a row are connected to a common word line extending in the row direction, one ends of the memory cells arranged in a column are connected to a common bit line extending in the column direction, the other ends of the memory cells are connected to a source line extending in the row or column direction, and the writing means applies the first voltage between the bit line and the source line connected to the memory cell to be written and applies the predetermined gate potential to the word line connected to the gate of the cell access transistor in the memory cell to be written in the first writing action, and applies the second voltage between the bit line and the source line connected to the memory cell to be written and applies the predetermined gate potential to the word line connected to the gate of the cell access transistor in the memory cell to be written in the second writing action.

According to the semiconductor memory device in the tenth characteristics, there can be provided a high-capacity semiconductor memory device capable of providing the effect in the first to ninth characteristics.

Furthermore, in addition to any one of the above characteristics, the semiconductor memory device according to the present invention is eleventh characterized in that the thickness of the gate insulation film of the cell access transistor is the same as that of the gate insulation film of the transistor constituting at least the writing means.

According to the semiconductor memory device in the eleventh characteristics, since the cell access transistor in the memory cell and the transistor constituting the writing means can be formed in the same transistor manufacturing steps, the manufacturing steps of the semiconductor memory device can be simplified and the manufacturing cost can be further low.

### BRIEF DESCRIPTION OF THE DRAWINGS

FIG. 1 is a circuit diagram schematically showing one constitution example of a memory cell array in one embodiment of a semiconductor memory device according to the present invention;

FIG. 2 is a circuit diagram schematically showing another constitution example of the memory cell array in one embodiment of the semiconductor memory device according to the present invention;

FIG. 3 is a schematic plan view showing a schematic planar constitution of a memory cell and the memory cell array used in one embodiment of the semiconductor memory device according to the present invention;

FIG. 4 is a schematic sectional view showing a sectional constitution of the memory cell and the memory cell array used in one embodiment of the semiconductor memory device according to the present invention;

FIG. 5 is a view showing one example of writing characteristics of a variable resistance element used in one embodiment of semiconductor memory device according to the present invention;

FIG. 6 is a view showing a voltage applying condition when a programming action (first writing action) is performed with respect to each memory cell in one embodiment of the semiconductor memory device according to the present invention;

FIG. 7 is a view showing a voltage applying condition when an erasing action (second writing action) is performed with respect to each memory cell in one embodiment of the semiconductor memory device according to the present invention;

FIG. 8 is a block diagram showing schematic constitution in one embodiment of the semiconductor memory device according to the present invention;

FIG. 9 is a view showing a voltage applying condition when the erasing action (second writing action) is performed in one embodiment of the semiconductor memory device according to the present invention;

FIG. 10 is a view showing a voltage applying condition when the programming action (first writing action) is performed in one embodiment of the semiconductor memory device according to the present invention;

FIG. 11 is a view showing a voltage applying condition when a reading action is performed in one embodiment of the semiconductor memory device according to the present invention;

FIG. 12 is a circuit diagram schematically showing one constitution example of a memory cell array incorporating a variable resistance element in a conventional technique;

FIG. 13 is a view showing a voltage applying condition in a programming action for a memory cell including one transistor and one variable resistance element in the conventional technique; and

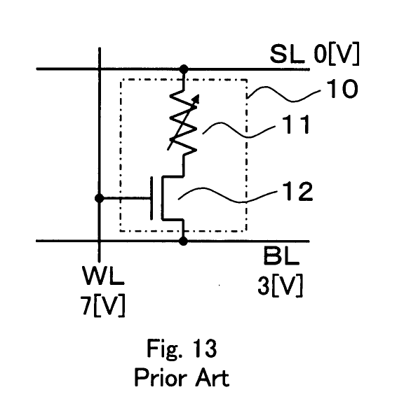

FIG. 14 is a view showing a voltage applying condition in an erasing action for the memory cell including one transistor and one variable resistance element in the conventional technique.

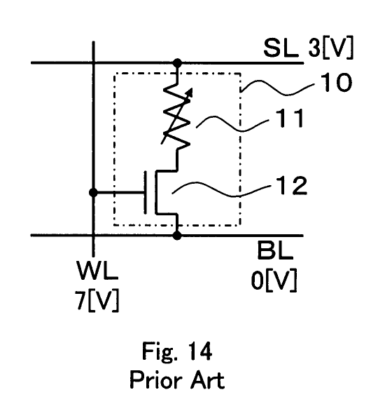

### DETAILED DESCRIPTION OF THE INVENTION

An embodiment of a semiconductor memory device (referred to as the device of the present invention occasionally hereinafter) according to the present invention will be described with reference to the drawings hereinafter.

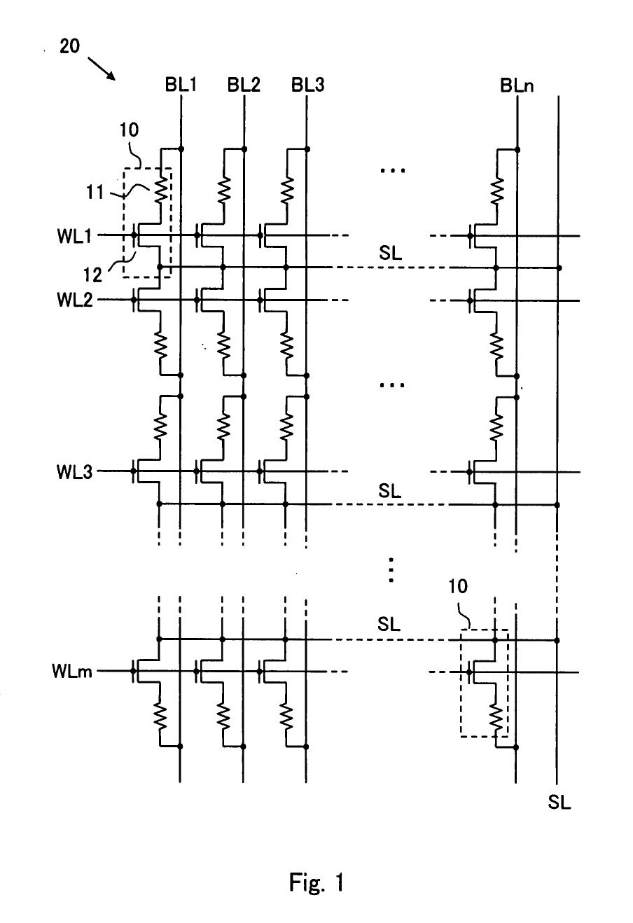

As shown in FIG. 1, the device of the present invention includes one or more memory cell arrays 20 in which a plurality of memory cells 10 are arranged in row and column directions, and, to select a predetermined memory cell or a memory cell group, a plurality of word lines WL1 to WLm and a plurality of bit lines BL1 to BLn are arranged in a row and column directions, respectively and a source line SL extending in the row direction is arranged. In addition, although the source line SL extends in the row direction parallel to the word lines WL1 to WLm and it is provided in each row and connected to other source lines in common outside the memory cell array 20 in FIG. 1, the source line SL may be shred with the two adjacent rows, or it may extend in the column direction instead of the row direction. Furthermore, it may be constituted such that a plurality of source lines SL are provided in one memory cell array 20 and they can select a certain memory cell or memory cell group like the word lines and bit lines.

In addition, the memory cell array 20 is not limited to the constitution of an equivalent circuit shown in FIG. 1, so that the device of the present invention is not limited by its specific circuit constitution as long as the memory cell array is provided by connecting the memory cells 10 each including the variable resistance element 11 and the cell access transistor 12 through the word lines and the bit lines and source lines,

According to this embodiment, the memory cell 10 forms a series circuit in which one end of the variable resistance element 11 is connected to the source or drain of the cell access transistor 12, in which the other end of the variable resistance element 11 is connected to each of the bit lines BL1 to BLn and the other of the source or drain of the cell access transistor 12 is connected to the source line SL and a gate of the cell access transistor 12 is connected to each of the word lines WL1 to WLm. The variable resistance element 11 is a nonvolatile memory element having two terminals and it can store information by shifting its electric resistance from a first state to a second state when a first write voltage is applied to both ends thereof, and shifting its electric resistance from the second state to the first state when a second write voltage having a polarity opposite to that of the first write voltage and having a different absolute value is applied to both ends thereof. The cell access transistor 12 is a MOSFET that is the same as that used in a MOSFET that constitutes peripheral circuits of the memory cell array 20 as will be described below and it is an enhancement-type N channel MOSFET in which a conductivity type of the source and the drain are N type and a threshold voltage is a positive voltage (for example, +0.1V to +1.5V).

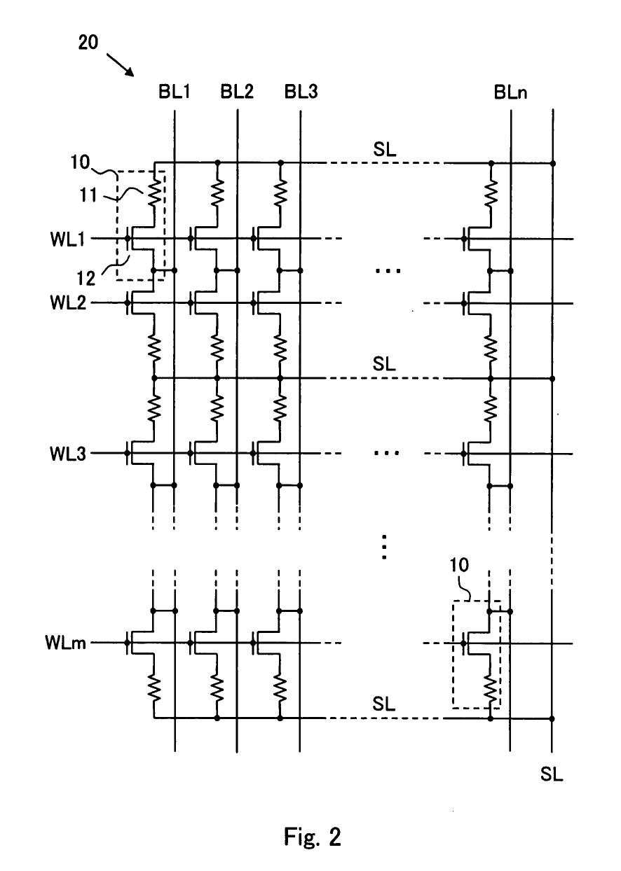

In addition, although the other end of the variable resistance element 11 is connected to each of the bit lines BL1 to BLn, and the other of the source or drain of the cell access transistor 12 is connected to the source line SL in the circuit constitution shown in FIG. 1, it may be such that the other end of the variable resistance element 11 is connected to the source line SL and the other of the source or drain of the cell access transistor 12 is connected to each of the bit line BL1 to BLn as shown in FIG. 2.

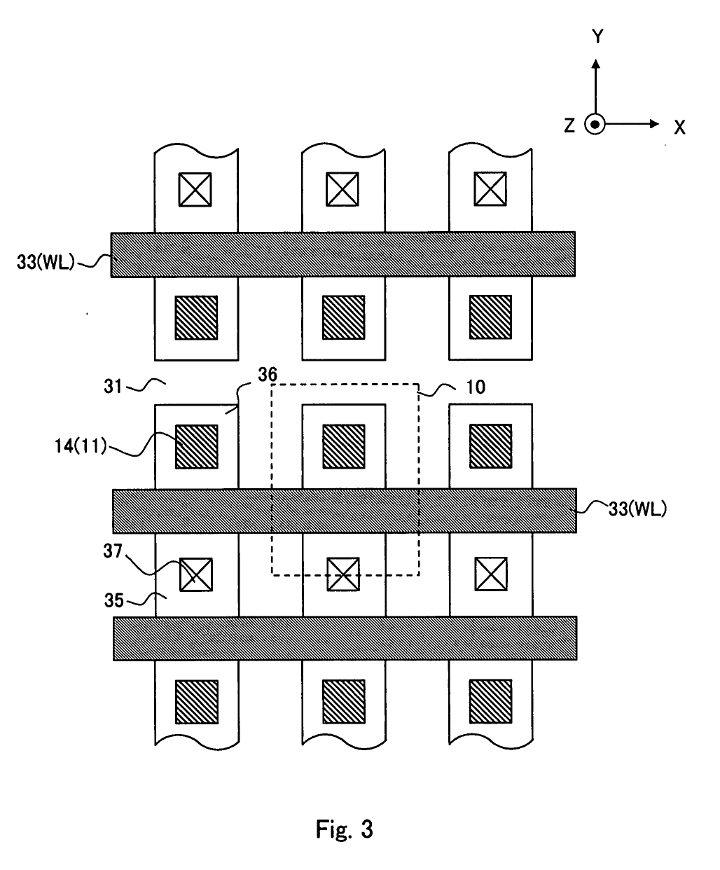

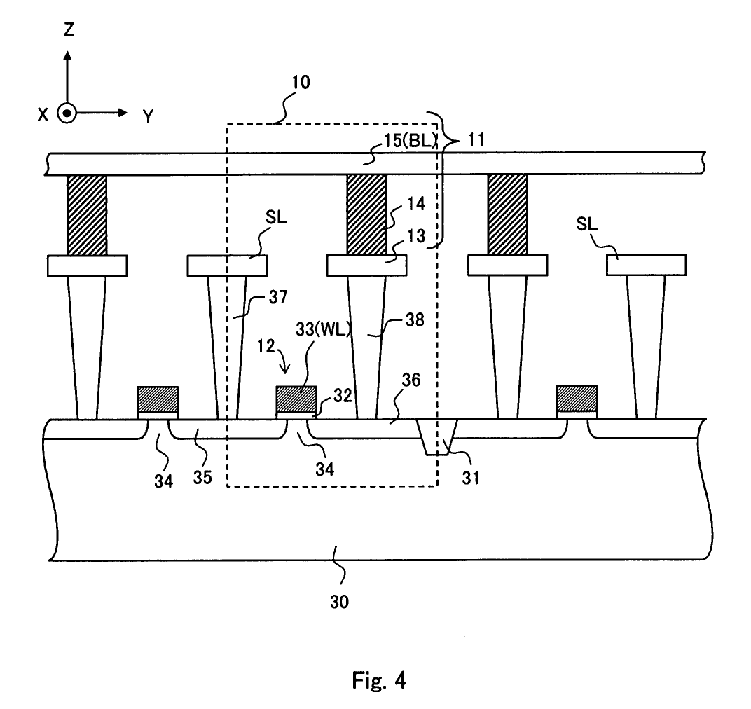

FIGS. 3 and 4 are a plan view and a sectional view schematically showing the circuit constitution of the memory cell 10 and the memory cell array 20 shown in FIG. 1, respectively. In addition, directions X, Y and Z shown in FIGS. 3 and 4 for descriptive purposes correspond to the row direction, the column direction, the direction perpendicular to the semiconductor substrate surface, respectively. FIG. 4 is a sectional view taken along a YZ surface. As shown in FIGS. 3 and 4, at least one part on the P type semiconductor substrate (or a P type well) 30 is an active area surface isolated by an element isolation film 31 such as a STI (Shallow Trench Isolation), in which a gate insulation film 32 is formed at least partly and a gate electrode 33 formed of a polycrystalline silicon, for example is formed so as to cover at least one part of the gate insulation film 32, a channel area 34 is formed under the gate insulation film 32, and impurity diffusion layers 35 and 36 having a conductivity type (N type) opposite to that of the semiconductor substrate 30 are formed on both sides of the channel region 34 to constitute the drain and source, respectively. Thus, the cell access transistor 12 is formed. The gate electrodes 33 of the cell access transistors 12 in the adjacent memory cells are connected in the row direction (X direction), whereby each word line (WL1 to WLm) is constituted.

A contact hole 37 filled with a conductive material is provided in an interlayer insulation film on the impurity diffusion layer 35 and connected to the source line SL extending in the row direction (X direction). In addition, a similar contact hole 38 is formed on the impurity diffusion layer 36 and connected to a lower electrode 13 of the variable resistance element 11. An upper electrode 15 of the variable resistance element 11 extends in the column direction (Y direction) and constitutes each bit line BL (BL1 to BLn). In addition, in the plan view in FIG. 3, the source line SL extending in the row direction (X direction) and each bit line BL (BL1 to BLn) extending in the column direction (Y direction) are not given to show the lower structure of them.

The variable resistance element 11 has a three-layer structure in which the lower electrode 13, a variable resistor 14 and the upper electrode 15 are sequentially laminated in general. In addition, although the element constitution and the material of the variable resistor 14 are not limited in particular as long as the variable resistance element 11 shifts its electric resistance from the first state to the second state when the first write voltage is applied to both ends and shifts its electric resistance from the second state to the first state when the second write voltage having the polarity opposite to that of the first write voltage and a different absolute value is applied to both ends. The variable resistor 14 may be formed of Perovskite-type oxide containing manganese such as Pr₍₁₋ₓ₎CaₓMnO₃, La₍₁₋ₓ₎CaₓMnO₃, La_{(1-x-y)}CaₓPb_{y}MnO₃, (where x<1, y<1, x+y<1), Sr₂FeMoO₆, or Sr₂FeWO₆, or manganese oxide such as Pr_{0.7}Ca_{0.3}MnO₃, La_{0.65}Ca_{0.35}MnO₃, and La_{0.65}Ca_{0.175}Pb_{0.175}MnO₃, or a material containing an oxide or oxynitride of the element selected from titanium, nickel, vanadium, zirconium, tungsten, cobalt, zinc, iron and copper, for example. In addition, the variable resistor 14 may have a structure in which the Perovskite-type oxide containing manganese or metal oxide, oxynitride is sandwiched by metal such as aluminum, copper, titanium, nickel, vanadium, zirconium, tungsten, cobalt, zinc, iron, or conductive oxide film or nitride film or oxynitride film containing the above metal. Thus, as described above, as long as the desired resistance state and a shift in resistance state can be provided such that the electric resistance shifts from the first state to the second state when the first write voltage is applied to both ends, and the electric resistance shifts from the second state to the first state when the second write voltage is applied to both ends, it is preferable that the above material is used to obtain desired characteristics although its constitution and material are not limited in particular.

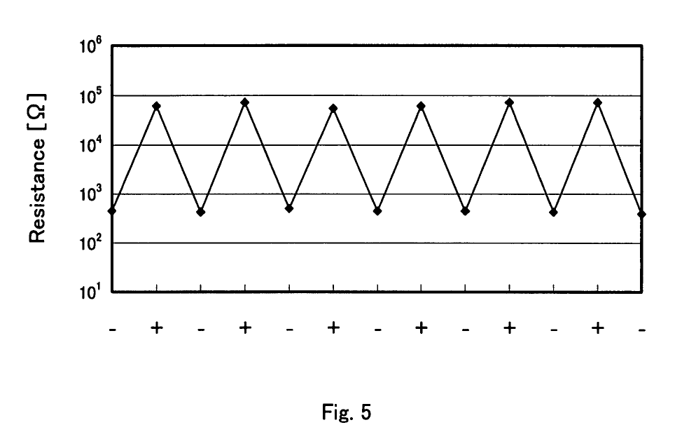

In addition, FIG. 5 shows switching state (write characteristics) of the electric resistance in response to voltage application when an oxynitride containing titanium is used in the variable resistor 14, as one example of the variable resistance element 11. According to the example shown in FIG. 5, when the first positive write voltage is applied to the lower electrode based on the upper electrode (shown by “+” in the drawing), the electric resistance of the variable resistance element 11 shifts from the low resistance state first state) to the high resistance state (second state) (first writing action) and adversely, when the second negative write voltage is applied to the lower electrode based on the upper electrode (shown by “−” in the drawing), the electric resistance of the variable resistance element 11 shifts from the high resistance state to the low resistance state (second writing action). Thus, the electric resistance of the variable resistance element 11 switches between the low resistance state and the high resistance state alternately in response to the switching of the polarity of the write voltage applied to both ends of the variable resistance element 11, so that two-level data (“0”/“1”) can be stored and written in the variable resistance element 11 by the switching of the resistance state.

In addition, according to the case of the memory case structure shown in FIGS. 3 and 4, in the first writing action, the reference potential of the upper electrode is supplied from the bit line BL and the first positive write voltage based on the upper electrode is applied from the source line SL to the lower electrode through the cell access transistor 12. Therefore, the first write voltage applied to the lower electrode based on the upper electrode is a voltage that drops from the gate potential of the cell access transistor 12 by a threshold voltage, so that the net voltage applied between the bit line BL and the source line SL is not applied to the variable resistance element 11. Meanwhile, in the second writing action, the reference potential of the upper electrode is supplied from the bit line BL and the second negative write voltage based on the upper electrode is applied from the source line SL to the lower electrode through the cell access transistor 12. However, since the absolute value of the second negative write voltage applied to the lower electrode based on the upper electrode is not the voltage dropped from the gate potential of the cell access transistor 12 by the threshold voltage, the net voltage applied between the bit line BL and the source line SL is applied to the variable resistance element 11. Therefore, when the variable resistance element 11 is so constituted that the absolute value of the first write voltage is smaller than the absolute value of the second write voltage, the voltage applied between the bit line BL and the source line SL in the first writing action and the second writing action (corresponding to the first voltage and the second voltage) can be lowered. That is, since it is not necessary to compensate the voltage drop by the threshold voltage in the first writing action, the voltage can be lowered by just that much.

In addition, in the case of the memory cell structure shown in FIGS. 3 and 4, the memory cell having the write characteristics shown in FIG. 5 has a voltage asymmetric property in the write voltage in which the first positive write voltage shown by “+” is lower than the second negative write voltage shown by “−” (absolute value).

Next, the writing action performed for each memory cell in the device of the present invention will be described in detail taking the case of the memory cell structure shown in FIGS. 3 and 4 as one example.

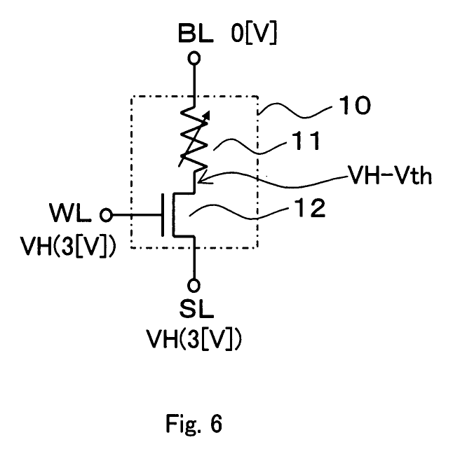

FIG. 6 shows a voltage applying condition at each part during the first writing action (referred to as the programming action hereinafter) with respect to each memory cell in the memory cell structure shown in FIGS. 3 and 4. At the time of the programming action, 0V, for example is applied to the bit line BL of the memory cell 10 and a voltage VH, +3V, for example is applied to the source line SL and a voltage VH, +3V, for example is applied to the word line WL. At this time, the voltage applied to the variable resistance element 11 on the side of the cell access transistor 12 (lower electrode side of the variable resistance element 11) is the voltage (VH−Vth) calculated by subtracting the threshold voltage Vth of the cell access transistor 12 from the gate voltage VH (+3V), 2.1V, for example, so that the positive voltage (VH−Vth), +2.1V, for example is applied to both ends of the variable resistance element 11 based on the upper electrode. Thus, a current path in which a current flows from the source line SL to the bit line BL is formed and the electric resistance of the variable resistance element 11 shifts from the low resistance state (first state) to the high resistance state (second state). Thus, the programming action of the memory cell 10 can be performed at a low voltage first write voltage) such as +2.1V applied to both ends of the variable resistance element 11.

In addition, although the voltage applied to the bit line BL may be fluctuated by ±1V from 0V, since the first write voltage is also fluctuated by that amount, it is necessary to fluctuate the voltage applied to the word line WL similarly to ensure a constant voltage as the first write voltage, so that the voltage applied to the bit line BL is preferably 0V. Thus, the ground potential 0V can be used as a set potential of the bit line BL like the peripheral circuit in the device of the present invention.

In addition, although the voltage applied to the source line SL may be fluctuated by the threshold voltage Vth of the cell access transistor 12 from the voltage VH (+3V for example), when it is the same as the voltage VH applied to the word line WL, the voltage value at the programming action can be shared, so that the peripheral circuits containing a voltage generation circuit can be simplified and the chip area can be reduced. Furthermore, when the power supply voltage is the same as the voltage VH, a booster circuit for generating the voltage VH is not needed.

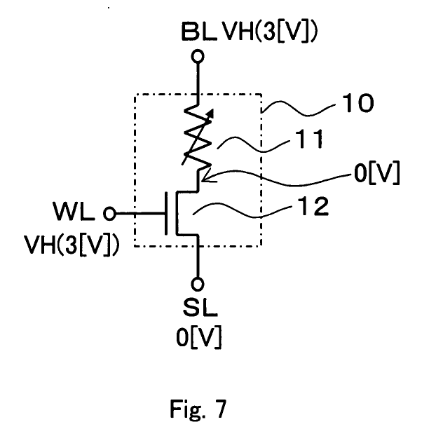

FIG. 7 shows a voltage applying condition at each part in the second writing action (referred to as the erasing action hereinafter) with respect to each memory cell in the memory cell structure shown in FIGS. 3 and 4. At the time of the erasing action, 0V, for example is applied to the source line SL of the memory cell 10 and a voltage VH, +3V, for example is applied to the bit line BL and the voltage VH, +3V, for example is applied to the word line WL. At this time, since the cell access transistor 12 is the N channel MOSFET, the 0V applied to the source line SL can be outputted to the drain side (lower electrode side of the variable resistance element 11) of the cell access transistor 12 as it is, the negative voltage −VH(−3V) is applied to both ends of the variable resistance element 11 based on the upper electrode. Thus, a current path in which a current flows from the bit line BL to the source line SL is formed and the electric resistance of the variable resistance element 11 shifts from the high resistance state (second state) to the low resistance state (first state). Thus, the erasing action of the memory cell 10 can be performed at the voltage (second write voltage) higher than that in the programming action, such as +3V that is the voltage (absolute value) applied to both ends of the variable resistance element 11.

In addition, although the voltage applied to the source line SL may be fluctuated by ±1V from 0V, since the second write voltage is fluctuated by that amount, it is necessary to fluctuate the voltage applied to the bit line BL similarly to ensure the constant voltage as the second write voltage, so that the voltage applied to the source line SL is preferably 0V. Thus, the ground potential 0V can be used as the set potential of the source line SL like the peripheral circuit in the device of the present invention.

Similarly, although the voltage applied to the bit line BL may be fluctuated by ±1V from the voltage VH (+3V for example), the voltage applied to the bit line BL is preferably VH in order to ensure the constant voltage as the second write voltage. Thus, since it can be the same as the voltage VH applied to the word line Wl, the voltage value at the time of erasing action can be shared, so that the peripheral circuits containing the voltage generation circuit can be simplified and the chip area can be reduced. Furthermore, when the power supply voltage is the same as the voltage VH, the booster circuit for generating the voltage VH is not needed.

Furthermore, since the voltage VH applied to the source line SL and the word line WL at the time of the programming action is the same as the voltage VH applied to the bit line BL and word line WL at the time of the erasing action, the same VH can be shared at the time of the programming and erasing actions, so that the voltage value at the time of writing action can be shared, and the peripheral circuits containing the voltage generation circuit can be simplified and the chip area can be further reduced.

Here, since the absolute value of the second write voltage applied to both ends of the variable resistance element at the time of the erasing action is defined by the voltage VH applied to the bit line BL, when the voltage VH is set so as to correspond to the second write voltage, the first write voltage (VH−Vth) applied to both ends of the variable resistance element at the time of programming is defined by the threshold voltage Vth of the cell access transistor. Therefore, the voltage applied to the source line SL and the word line WL at the time of programming action and the voltage applied to the bit line BL and the word line WL at the time of the erasing action can be shared by adjusting the voltage asymmetric property of the first and second write voltages with the threshold voltage Vth of the cell access transistor.

Here, when the power supply voltage is lower than the voltage VH, when it is +1.8V, for example, although a booster circuit for generating the voltage VH (+3V, for example) is needed, only one booster circuit is needed. In addition, like the conventional example, when the write voltage characteristics of the variable resistance element has the symmetric write voltage characteristics in which the absolute values of the first write voltage and the second write voltage are the same, since it is necessary to apply the voltage (VH+Vth) that is higher than the voltage VH by the threshold voltage or more, to the word line WL, a booster circuit for that voltage (VH+Vth) is needed separately and the number of boost stages of the booster circuit becomes not less than the that of the booster circuit for the voltage VH, so that the area occupied by the peripheral circuits is increased. However, according to this device of the present invention, the above problem is solved by the asymmetric write voltage characteristics of the variable resistance element.

Next, a description will be made of voltage applying conditions to the word lines WL1 to WLm, bit lines BL1 to BLn and source line SL of the memory cell array 20 shown in FIG. 1 in the programming action and the erasing action with respect to each memory cell.

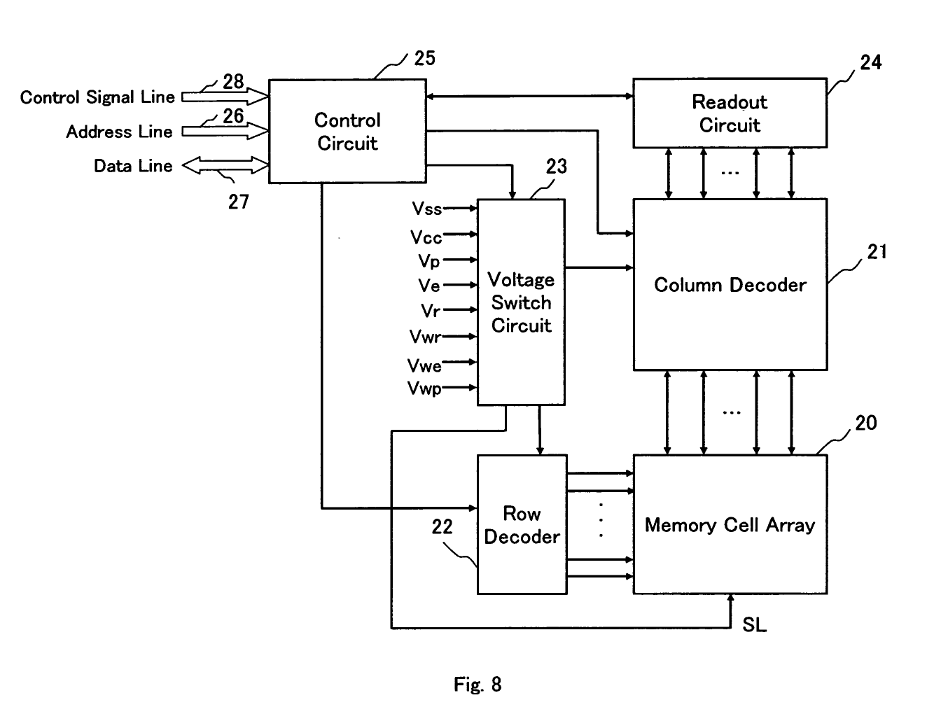

First, a description will be made of a peripheral circuit constitution for applying a predetermined voltage as will be described below, to each of the word lines WL1 to WLm, bit lines BL1 to BLn, and source line SL. FIG. 8 schematically shows one example of the peripheral circuit constitution of the device of the present invention.

As shown in FIG. 8, the device of the present invention comprises a column decoder 21, a row decoder 22, a voltage switch circuit 23, a readout circuit 24, and a control circuit 25 around the memory cell array 20 shown in FIG. 1.

The column decoder 21 and the row decoder 22 select a target memory cell in the reading action, the programming action (first write action) or the erasing action (second write action), from the memory cell array 20 based on an address input inputted from an address line 26 to the control circuit 25. In the normal reading operation, the row decoder 22 selects the word line of the memory cell array 20 based on the signal inputted to the address line 26, and the column decoder 21 selects the bit line of the memory cell array 20 based on the address signal inputted to the address line 26. In addition, in the programming action and the erasing action and a verifying action associated with the above actions (reading action for verifying the memory state of the memory cell after the programming action and the erasing action), the row decoder 22 selects one or more word lines of the memory cell array 20 based on a row address designated by the control circuit 25, and the column decoder 21 selects one or more bit lines of the memory cell array 20 based on a column address designated by the control circuit 25. The memory cell connected to the word line selected by the row decoder 22 and the bit line selected by the column decoder 21 is selected as the selected memory cell. More specifically, the gate of the cell access transistor in the selected target memory cell is connected to the selected word line and one end of the selected memory cell (the upper electrode of the variable resistance element in this embodiment) is connected to the selected bit line.

The control circuit 25 controls the programming action and erasing action including a batch erasing action), and reading action. The control circuit 25 controls the row decoder 22, the column decoder 21, the voltage switch circuit 23, and the reading, programming and erasing actions in the memory cell array 20 based on the address signal inputted from the address line 26, the data inputted from a data line 27 (at the time of programming), and a control input signal inputted from a control signal line 28. According to the example shown in FIG. 7, the control circuit 25 comprises a function as a general address buffer circuit, data input/output buffer circuit and control input buffer circuit although they are not shown.

The voltage switch circuit 23 switches each of the voltages applied to the word lines (selected word line and unselected word lines), the bit lines (selected bit line and unselected bit lines) and the source line required for the reading, programming and erasing actions of the memory cell array 20 based on an operation mode, and supplies it to the memory cell array 20. Therefore, the voltages applied to the selected word line and the unselected word lines are supplied from the voltage switch circuit 23 through the row decoder 22, the voltages applied to the selected bit line and the unselected bit lines are supplied from the voltage switch circuit 23 through the column decoder 21, and the voltage applied to the source line is directly supplied from the voltage switch circuit 23. In addition, in FIG. 7, reference character Vcc designates the power supply voltage of the device of the present invention, reference character Vss designates the ground voltage, reference character Vr designates the readout voltage, reference character Vp designates the supply voltage for the programming action (absolute value of the first voltage applied to both ends of the selected memory cell), reference character Ve designates the supply voltage for the erasing action (absolute value of the second voltage applied to both ends of the selected memory cell), reference character Vwr designates the selected word line voltage for the reading action, reference character Vwp designates the selected word line voltage for the programming action, and reference character Vwe designates the selected word line voltage for the erasing action. As describe above, according to this embodiment, the supply voltage Vp for the programming action, the supply voltage Ve for the erasing action, the selected word line voltage Vwp for the programming action, and the selected word line voltage Vwe for the erasing action are all the same as the voltage VH and can be shared. Therefore, in FIG. 8, each input voltage to the voltage switch circuit 23 is generalized.

The readout circuit 24 determines the state of the stored data (resistance state) by comparing a readout current flowing from the bit line selected by the column decoder 21 to the source line through the selected memory cell with a reference current directly, or with a reference voltage after the above current has been converted to a voltage and transfers the result of the determination to the control circuit 25 to be outputted to the data line 27.

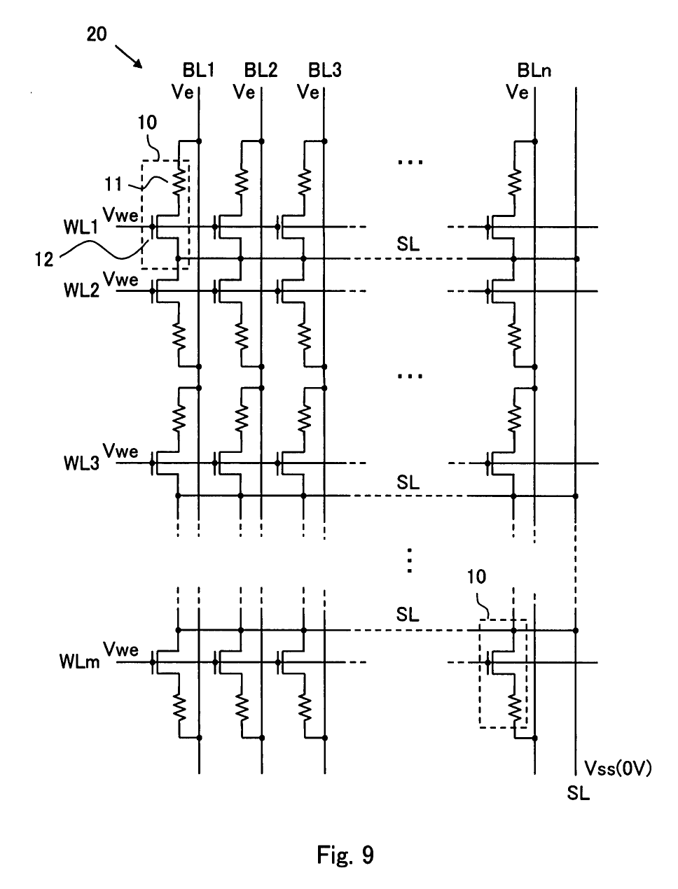

Next, a description will be made of the voltage applying condition when the memory cell array 20 is erased as one unit by batch processing. When the memory cell array 20 is erased as a batch unit, as shown in FIG. 9, all of the word line WL1 to WLm are selected by the row decoder 22 as the selected word lines, and the predetermined selected word line voltage Vwe (=VH, 3V, for example) is applied thereto. In addition, all of the bit lines BL1 to BLn are selected by the column decoder 21 as the selected bit lines and the erase voltage Ve (=VH, 3V, for example) is applied thereto. In addition, 0V (ground voltage Vss) is applied to the source line SL. Thus, the cell access transistors of all of the memory cells are all turned on and 0V applied to the source line SL is applied to the lower electrode of each variable resistance element and at the same time, the erase voltage Ve (=VH, 3V, for example) is applied to the upper electrode of each variable resistance element through each of the bit lines BL1 to BLn, so that the negative voltage (−Ve) is applied to the lower electrode based on the upper electrode at both ends of each variable resistance element. Thus, the erasing action for each memory cell shown in FIG. 7 is performed for all of the memory cells and the resistance state of the variable resistance element of each memory cell shifts from the second state (high resistance state) to the first state (low resistance state). In addition, the pulse width of the voltage pulse (voltage applying time required for the erasing action) of the erase voltage Ve is defined by the time in which the selected word line voltage Vwe is applied to the word line WL1 to WLm and the erase voltage Ve is applied to the bit lines BL1 to BLn at the same time. That is, either the application of the selected word line voltage Vwe or the erase voltage Ve may be started first or ended first.

In addition, in a case where certain memory cells in the memory cell array 20 are to be erased as the batch processing, when the plurality of memory cells in one or more rows are erased by the batch processing, for example, one or more word lines corresponding to the rows to be erased by the batch processing are selected and the selected word line voltage Vwe is applied to the selected word lines only and 0V (ground voltage Vss) is applied to the other unselected word lines. Thus, only the cell access transistors of the selected memory cells connected to the selected word lines are turned on and the negative voltage (−Ve) is applied to the lower electrodes based on the upper electrodes at both ends of the variable resistance elements, so that certain memory cells in one or more rows in the memory cell array 20 can be erased by the batch processing. In addition, when the plurality of word lines are selected arbitrarily, a function for selecting the plurality of word lines arbitrarily is to be added to the row decoder 22.

In addition, in a case where certain memory cells in the memory cell array 20 are to be erased by the batch processing, when a plurality of memory cells in one or more columns are erased by the batch processing, for example, one or more bit lines corresponding to the columns to be erased by the batch processing are selected and the erase voltage Ve is applied to the selected bit lines only and 0V (ground voltage Vss) is applied to the other unselected bit lines or the unselected bit lines are made to be in a floating state (high impedance state), so that the negative voltage (−Ve) is only applied to the lower electrode based on the upper electrode at both ends of the variable resistance element of the selected memory cells connected to the selected bit lines, and certain memory cells in one or more columns in the memory cell array 20 can be erased by the batch processing. In addition, when the plurality of bit lines are selected arbitrarily, a function for selecting the plurality of bit lines arbitrarily is to be added to the column decoder 21.

Furthermore, in the case where certain memory cells in the memory cell array 20 are to be erased by the batch processing, when a plurality of memory cells in one or more rows and columns are erased by the batch processing, for example, similar to the above cases, one or more word lines corresponding to the rows to be erased by the batch processing are selected and the selected word line voltage Vwe is applied to the selected word lines only and 0V (ground voltage Vss) is applied to the other unselected word lines. Furthermore, one or more bit lines corresponding to the columns to be erased by the batch processing are selected and the erase voltage Ve is applied to the selected bit lines only and 0V (ground voltage Vss) is applied to the other unselected bit lines or the unselected bit lines are made to be in a floating state (high impedance state), so that the negative voltage (−Ve) is only applied to the lower electrode based on the upper electrode at both ends of the variable resistance element of the memory cells to be erased, and certain memory cells in one or more rows and columns in the memory cell array 20 can be erased by the batch processing.

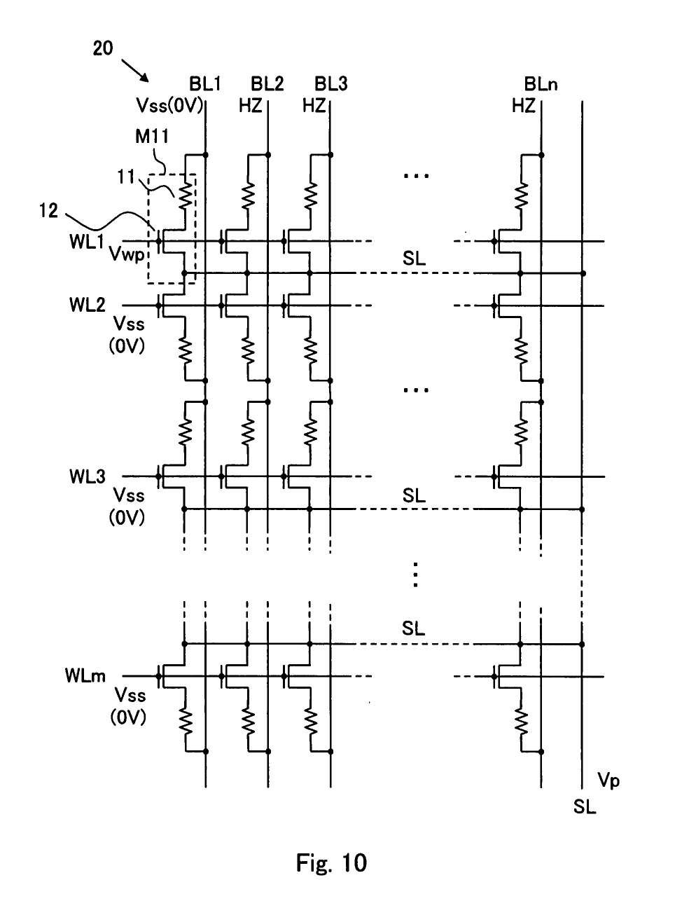

Next, a description will be made of a voltage applying condition when the programming action (first write action) is performed for each memory cell in the memory cell array 20 separately. In a case where a single memory cell is to be programmed, as shown in FIG. 10, when a memory cell M11 connected to the word line WL1 and the bit line BL1 is to be separately programmed, for example, the word line WL1 is selected by the row decoder 22 as the selected word line, a predetermined selected word line voltage Vwp (=VH, 3V, for example) is applied thereto, and 0V (ground voltage Vss) is applied to the other unselected word lines WL2 to WLm. In addition, the bit line BL1 is selected by the column decoder 21 as the selected bit line and 0V (ground voltage Vss) is applied thereto and the other unselected bit lines BL2 to BLn are made to be the floating state (high impedance state). The program voltage Vp (=VH, 3V, for example) is applied to the source line SL. Thus, the cell access transistor in the selected memory cell M11 is turned on and the program voltage Vp applied to the source line SL is applied to the lower electrode of the variable resistance element through the cell access transistor up to a voltage value (Vwp−Vth) calculated by subtracting the threshold voltage (Vth) of the cell access transistor from the gate voltage (Vwp) of the cell access transistor. At the same time, since 0V (ground voltage Vss) is applied to the upper electrode of the variable resistance element through the bit line BL1, the positive voltage (Vwp−Vth) is applied to the lower electrode based on the upper electrode at both ends of the variable resistance element of the selected memory cell M11 only. Thus, the programming action for each memory cell shown in FIG. 6 can be performed for the selected memory cell M11, and the resistance state of the variable resistance element of the selected memory cell M11 shifts from the first state (low resistance state) to the second state (high resistance state).

In addition, the pulse width of the voltage pulse of the program voltage (voltage applying time required for the programming action) is defined by the time in which the selected word line voltage Vwp is applied to the word line WL1 and the program voltage Vp is applied to the source line SL at the same time. That is, either the application of the selected word line voltage Vwp or the program voltage Vp may be started first or ended first.

Here, according to a voltage applying condition when the plurality of memory cells in the memory cell array 20 are programmed (first write action) at the same time, the memory cells to be programmed are to be arranged in the same one row or the same one column. For example, when the memory cells in the same one row are programmed at the same time, similar to the programming action for each memory cell, the predetermined selected word line voltage Vwp (3V, for example) is applied to the word line selected by the row decoder 22 and 0V (ground voltage Vss) is applied to the other unselected word lines. Furthermore, the bit line connected to the plurality of memory cells to be programmed is selected by the column decoder 21 as the selected bit line and 0V (ground voltage Vss) is applied thereto and the other unselected bit lines are made to be the floating state (high impedance state). The program voltage Vp (3V, for example) is applied to the source line SL. Thus, the positive voltage (Vwp−Vth) is only applied to the lower electrode based on the upper electrode in the selected memory cells to be programmed, so that the programming action for each memory cell shown in FIG. 6 can be performed for the plurality of selected memory cells. Thus, the resistance state of the variable resistance element of each selected memory cell shifts from the first state (low resistance state) to the second state (high resistance state). In addition, when the memory cells in the same one row are programmed at the same time, each word line connected to the plurality of memory cells to be programmed is selected by the row decoder 22 as the selected word line and the predetermined selected word line voltage Vwp (3V, for example) is applied to the selected word line and 0V (ground voltage Vss) is applied to the other unselected word lines. Furthermore, 0V (ground voltage Vss) is applied to the bit line selected by the column decoder 21 and the other unselected bit lines are made to be the floating state (high impedance state). The program voltage Vp (3V, for example) is applied to the source line SL. Thus, the positive voltage (Vwp−Vth) is only applied to the lower electrode based on the upper electrode in the selected memory cells to be programmed, so that the first write action shown in FIG. 6 is performed for the plurality of selected memory cells and the resistance state of the variable resistance element of each selected memory cell shifts from the first state (low resistance state) to the second state (high resistance state).

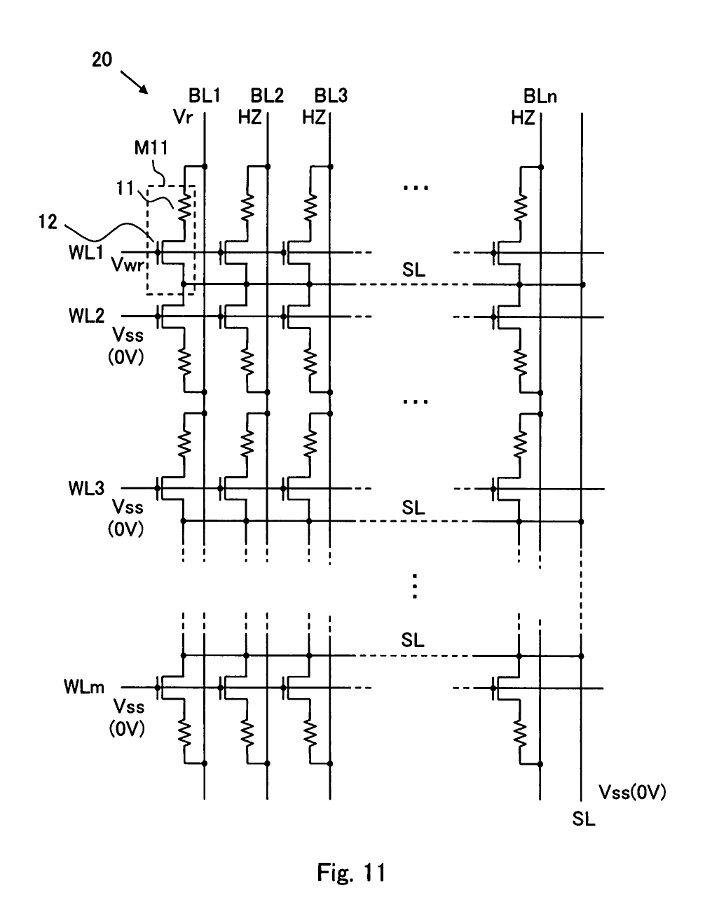

Next, a description will be made of a voltage applying condition when the reading action is performed for each memory cell in the memory cell array 20 separately. In a case where a single memory cell is to be read, as shown in FIG. 11, when a memory cell M11 connected to the word line WL1 and the bit line BL1 is to be read, for example, the word line WL1 is selected by the row decoder 22 as the selected word line, a predetermined selected word line voltage Vwr (1.5V, for example) is applied thereto, and 0V (ground voltage Vss) is applied to the other unselected word lines WL2 to WLm. In addition, the bit line BL1 is selected by the column decoder 21 as the selected bit line and a read voltage Vr (1V, for example) is applied thereto and the other unselected bit lines BL2 to BLn are made to be the floating state (high impedance state). In addition, 0V (ground voltage) is applied to the source line SL. Thus, the cell access transistor in the selected memory cell M11 is turned on and 0V (ground voltage) applied to the source line SL is applied to the lower electrode of the variable resistance element through the cell access transistor and at the same time, the read voltage Vr (1V, for example) is applied to the upper electrode of the variable resistance element through the bit line BL1, so that a read current corresponding to the resistance state of the variable resistance element flows from the upper electrode to the lower electrode in the variable resistance element and the read current flows from the selected bit line BL1 to the source line SL. Thus, when the read current is detected by the readout circuit 24 through the column decoder 21, the data stored in the selected memory cell M11 can be read out. In addition, the voltage applying condition of this reading action can be applied to the verifying action accompanied with the erasing and programming actions similarly.

### (Another Embodiment)

Next, another embodiment of the present invention will be described.

(1) Although the constitutions shown in FIGS. 3 and 4 are assumed as the schematic plan constitution and sectional constitution of the memory cell 10 and the memory cell array 20 in the above embodiment, the constitutions of the memory cell 10 and the memory cell array 20 are not limited to the above constitutions. For example, it may be such that the contact hole 37 formed on the impurity diffusion layer 35 of the cell access transistor 12 is connected to the bit line BL (BL1 to BLn) extending in the column direction (Y direction) instead of the source line and reversely, the upper electrode 15 of the variable resistance element 11 extends in the row direction (X direction) or the column direction (Y direction) and constitutes the source line SL. In this case, one example of the equivalent circuit of the memory cell array 20 is as shown in FIG. 2.

As shown in FIG. 2, since the source line SL is directly connected to the upper electrode 15 of the variable resistance element 11 and the bit line BL is connected to the lower electrode 13 of the variable resistance element 11 through the cell access transistor 12, the voltage polarity applied between the source line SL and the bit line BL is converted between the upper electrode 15 and the lower electrode 13 of the variable resistance element 11 as compared with the above embodiment. Therefore, the voltages applied to the source line SL and the bit line BL in the writing action in the above embodiment is to be exchanged to each other.

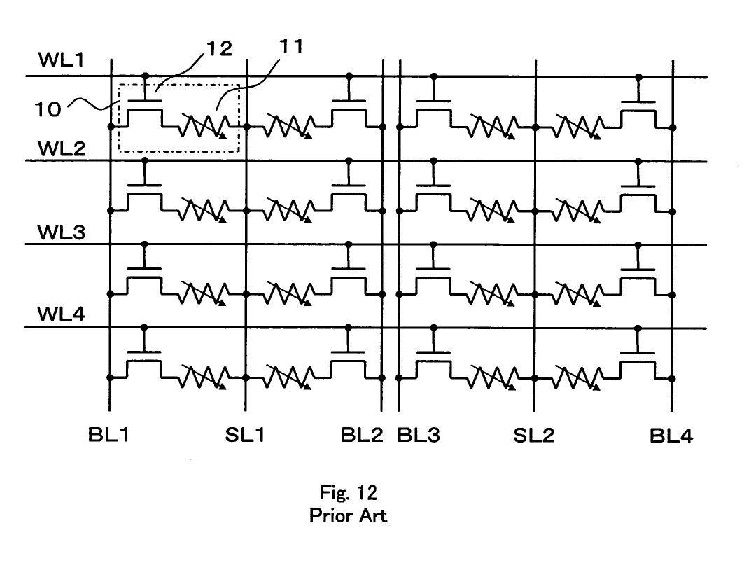

Furthermore, the constitution of the memory cell array 20 may be the memory cell array constitution disclosed in the Japanese Unexamined Patent Publication No. 2004-185755 as shown in FIG. 12.

### (2) Although the description has been made of the case where one memory cell array 20 is provided to simplify the description in the above embodiment, the plurality of memory cell arrays 20 may be provided.

(3) Although the description has been made assuming that the write voltage characteristics are asymmetric such that the absolute value of the second write voltage is greater than the absolute value of the first write voltage in the above embodiment, in a case where the absolute value of the first write voltage is greater than the absolute value of the second write voltage, the voltage applying conditions of the programming action and the erasing action in the above embodiment are to be exchanged.

The semiconductor memory device according to the present invention can be applied to a semiconductor memory device provided with a memory cell including a variable resistance element having two terminals that can store information by varying its electric resistance between a first stat and a second state when voltages having different polarity are separately applied to both ends thereof, and a cell access transistor whose source or drain is connected to one end of the variable resistance element.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A semiconductor memory device comprising:
a memory cell having a variable resistance element having two terminals and being capable of storing information in accordance with a shift of an electric resistance between a first state and a second state by applying voltages having different polarities to both ends respectively and a cell access transistor having a source or a drain connected to one end of the variable resistance element; and
writing means for performing two writing actions such as a first writing action shifting the electric resistance of the variable resistance element from the first state to the second state by applying a predetermined first voltage between both ends of the memory cell and a predetermined gate potential to a gate of the cell access transistor, and a second writing action shifting the electric resistance of the variable resistance element from the second state to the first state by applying a predetermined second voltage having a polarity opposite to that of the first voltage between both ends of the memory cell and a predetermined gate potential to the gate of the cell access transistor, wherein
the polarity and an absolute value of the voltage to be applied to both ends of the variable resistance element in the memory cell to be written in the first writing action are different from those in the second writing action.

2. The semiconductor memory device according to claim 1, wherein
the polarity and absolute value of a voltage at both ends between the source and drain of the cell access transistor in the memory cell to be written in the first writing action are different from those in the second writing action.

3. The semiconductor memory device according to claim 2, wherein
a bias condition of the cell access transistor in each of the first writing action and the second action is set such that the absolute value of the voltage at both ends between the source and the drain of the cell access transistor in the memory cell to be written in either one of the first writing action or the second writing action is smaller than that in the other writing action when the absolute value of the voltage at both ends of the variable resistance element in the memory cell to be written is greater than that in the other writing action.

4. The semiconductor memory device according to claim 1, wherein
absolute values of the first voltage and the second voltage are the same.

5. The semiconductor memory device according to claim 1, wherein
the cell access transistor is an enhancement-type N channel MOSFET.

6. The semiconductor memory device according to claim 5, wherein
the higher one of potentials at both ends of the memory cell to be written is the same level as a gate potential of the cell access transistor in the memory cell to be written in the first writing action.

7. The semiconductor memory device according to claim 5, wherein
the higher one of potentials at both ends of the memory cell to be written is the same level as a gate potential of the cell access transistor in the memory cell to be written in the second writing action.

8. The semiconductor memory device according to claim 5, wherein
the higher one of potentials at both ends of the memory cell to be written is the same level as a gate potential of the cell access transistor in the memory cell to be written in the first writing action and
the higher one of potentials at both ends of the memory cell to be written is the same level as the gate potential of the cell access transistor in the memory cell to be written in the second writing action.

9. The semiconductor memory device according to claim 5, wherein
the higher one of potentials at both ends of the memory cell to be written in the first writing action is the same level as that of the second writing action.

10. The semiconductor memory device according to claim 5, wherein
the gate potential of the cell access transistor in the memory cell to be written in the first writing action is the same level as that in the second writing action.

11. The semiconductor memory device according to claim 5, wherein
the higher one of potentials at both ends of the memory cell to be written in the first writing action is the same level as that of the second writing action and
the gate potential of the cell access transistor in the memory cell to be written in the first writing action is the same level as that in the second writing action.

12. The semiconductor memory device according to claim 1 comprising:
a memory cell array including the memory cells arranged in a row and column direction, wherein
the gates of the cell access transistors in the memory cells arranged in a row are connected to a common word line extending in the row direction, one ends of the memory cells arranged in a column are connected to a common bit line extending in the column direction, the other ends of the memory cells are connected to a source line extending in the row or column direction, and
the writing means applies the first voltage between the bit line and the source line connected to the memory cell to be written and applies the predetermined gate potential to the word line connected to the gate of the cell access transistor in the memory cell to be written in the first writing action, and applies the second voltage between the bit line and the source line connected to the memory cell to be written and applies the predetermined gate potential to the word line connected to the gate of the cell access transistor in the memory cell to be written in the second writing action.

13. The semiconductor memory device according to claim 1, wherein
a thickness of the gate insulation film of the cell access transistor is the same as that of the gate insulation film of a transistor constituting at least the writing means.
